(19) United States
(12) Patent Application Publication
(10) Pub. No.: US 2018/0062559 A1
(43) Pub. Date: Mar. 1, 2018

(54) SYSTEMS AND METHODS FOR IMPROVED INSTALLATION OF PHOTOVOLTAIC ASSEMBLIES

(71) Applicant: SUNPOWER CORPORATION, San Jose, CA (US)

(72) Inventors: John Paul Kapla, Mill Valley, CA (US); Kyle Donald Feldmann, Richmond, CA (US)

(21) Appl. No.: 15/253,814

(22) Filed: Aug. 31, 2016

(51) Int. Cl. H02S 20/23; H02S 30/10; H01L 31/049; F16B 5/12; F16B 5/06

(52) U.S. Cl. CPC H02S 20/23; H02S 30/10; F16B 5/0685; F16B 5/12; H01L 31/049

(57) ABSTRACT

PV assemblies for converting solar radiation into electrical energy, and methods of installation thereof, are disclosed herein. A PV assembly can include a mounting structure for mounting or supporting PV modules of a PV array. The PV assembly can include at least one PV module having several solar cells encapsulated within a PV laminate. A PV frame may at least partially surround the PV laminate. The PV assembly can further include at least one positioning or alignment device for facilitating alignment of PV modules in the array. The positioning or alignment device can include a support engagement feature for engaging the mounting structure and a module engagement feature for engaging the at least one PV module of the array. In various embodiments, the positioning or alignment device sets a predetermined distance between the mounting structure and at least one PV module.

### BACKGROUND

Solar power has long been viewed as an important alternative energy source. To this end, substantial efforts and investments have been made to develop and improve upon solar energy collection technology. Of particular interest are residential-, industrial- and commercial-type applications in which relatively significant amounts of solar energy can be collected and utilized in supplementing or satisfying power needs. One way of implementing solar energy collection technology is by assembling an array of multiple solar modules.

One type of solar energy system is a solar photovoltaic system. Solar photovoltaic systems (“photovoltaic systems”) can employ solar panels made of silicon or other materials (e.g., III-V cells such as GaAs) to convert sunlight into electricity. Photovoltaic systems typically include a plurality of photovoltaic (PV) modules (or “solar tiles”) interconnected with wiring to one or more appropriate electrical components (e.g., switches, inverters, junction boxes, etc.)

A typical conventional PV module includes a PV laminate or panel having an assembly of crystalline or amorphous semiconductor devices (“PV cells” or “solar cells”) electrically interconnected and encapsulated within a weather-proof barrier. One or more electrical conductors are housed inside the PV laminate through which the solar-generated current is conducted.

Regardless of an exact construction of the PV laminate, most PV applications entail placing an array of solar modules at the installation site in a location where sunlight is readily present. This is especially true for residential, commercial or industrial applications in which multiple solar modules are desirable for generating substantial amounts of energy, with the rooftop of the structure providing a convenient surface at which the solar modules can be placed.

In some arrangements, solar modules are placed side-by-side in an array. Each solar module can be mounted to a support structure, such as a roof, by coupling the module to a mounting structure (e.g., a rail) by way of a coupling member (e.g., a clamp, clip, anchor or mount). It can be challenging to couple modules side-by-side while also ensuring that adjacent modules are positioned properly on the mounting structure. Accordingly, there remains a continuing need for improved systems and methods for mounting solar modules to a support structure with minimal installation time and/or resources.

### BRIEF DESCRIPTION OF THE DRAWINGS

The following drawings illustrate by way of example and not limitation. For the sake of brevity and clarity, every feature of a given structure is not always labeled in every figure in which that structure appears. Identical reference numbers do not necessarily indicate an identical structure. Rather, the same reference number may be used to indicate a similar feature or a feature with similar functionality, as may non-identical reference numbers. The figures are not drawn to scale.

FIG. 1 depicts a top-down view of a photovoltaic (PV) module, in accordance with an embodiment of the present disclosure;

FIG. 2 depicts a top-down view of a PV assembly, in accordance with an embodiment of the present disclosure;

FIG. 3 depicts a side view of a PV assembly, in accordance with an embodiment of the present disclosure;

FIG. 4 depicts a bottom-up view of a back side of a PV assembly, in accordance with an embodiment of the present disclosure;

FIG. 5 depicts a perspective view of an alignment device, in accordance with an embodiment of the present disclosure;

FIG. 6 depicts a perspective view of an alignment device, in accordance with an embodiment of the present disclosure;

FIG. 7 depicts a perspective view of a PV assembly, in accordance with an embodiment of the present disclosure;

FIG. 8 depicts a bottom-up view of a back side of a PV assembly, in accordance with an embodiment of the present disclosure;

FIG. 9 depicts a flowchart listing operations in a method for assembling a PV array, in accordance with an embodiment of the present disclosure.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

Certain terminology may be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “axial”, and “lateral” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

Terminology—The following paragraphs provide definitions and/or context for terms found in this disclosure (including the appended claims):

This specification includes references to “one embodiment” or “an embodiment.” The appearances of the phrases “in one embodiment” or “in an embodiment” do not necessarily refer to the same embodiment. Particular features, structures, or characteristics can be combined in any suitable manner consistent with this disclosure.

The term “comprising” is open-ended. As used in the appended claims, this term does not foreclose additional structure or steps.

Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

As used herein, the terms “first,” “second,” etc. are used as labels for nouns that they precede, and do not imply any type of ordering (e.g., spatial, temporal, logical, etc.). For example, reference to a “first” encapsulant layer does not necessarily imply that this encapsulant layer is the first encapsulant layer in a sequence; instead the term “first” is used to differentiate this encapsulant from another encapsulant (e.g., a “second” encapsulant).

The terms “a” and “an” are defined as one or more unless this disclosure explicitly requires otherwise.

The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

As used herein, “inhibit” is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

As used herein, the term “substantially” is defined as largely but not necessarily wholly what is specified (and includes what is specified; e.g., substantially 90 degrees includes 90 degrees and substantially parallel includes parallel), as understood by a person of ordinary skill in the art. In any disclosed embodiment, the terms “substantially,” “approximately,” and “about” may be substituted with “within [a percentage] of” what is specified, where the percentage includes 0.1, 1, 5, and 10 percent.

In the following description, numerous specific details are set forth, such as specific operations, in order to provide a thorough understanding of embodiments of the present disclosure. It will be apparent to one skilled in the art that embodiments of the present disclosure may be practiced without these specific details. In other instances, well-known techniques are not described in detail in order to not unnecessarily obscure embodiments of the present invention. The feature or features of one embodiment can be applied to other embodiments, even though not described or illustrated, unless expressly prohibited by this disclosure or the nature of the embodiments.

Various embodiments disclosed herein relate to mounting an array of solar modules to a support surface or structure, such as a roof. For example, a mounting structure, such as a rail, can be attached to the roof or other support structure by way of one or more roof anchors. Solar modules can be positioned atop the rails adjacent to one another and can be coupled to the rails by way of a coupling member, such as a clamp assembly. When installing solar modules to form a photovoltaic (PV) array, an assembler may encounter various challenges. For example, the assembler may attempt to bring a rows of solar modules into alignment so as to install an array in an even, level or straight line for aesthetic purposes and/or to optimize space. In many circumstances, it can be challenging to align rows of an array. Accordingly, various embodiments disclosed herein are configured to assist an assembler in constructing an array by facilitating positioning of PV modules in an array. In one embodiment, the installer can set the positioning or align a first or front row of an array. The first or front row of the array can then be used as a guide to align additional rows of an array. For example, in some embodiments, an alignment device is provided to aid in alignment of one or more rows and/or columns of a photovoltaic PV array to enable minimal installation times and resources.

Improved PV assemblies for converting solar radiation to electrical energy and methods of installation thereof are disclosed herein. PV arrays comprising a plurality PV modules are also described herein. A PV assembly can include a mounting structure and/or a support structure for mounting or supporting PV modules of an array. The PV assembly can include at least one PV module having a front side and a back side opposite the front side. PV modules can include a plurality of solar cells encapsulated within a PV laminate. In some embodiments, a PV module includes a frame at least partially surrounding the PV laminate. The PV assembly can further include at least one positioning or alignment device for facilitating alignment of PV modules in the array. The positioning or alignment device can include a support engagement feature for engaging the mounting structure and a module engagement feature for engaging the at least one PV module of the array. In various embodiments, the positioning or alignment device sets a predetermined distance between the mounting and/or support structure and at least one PV module.

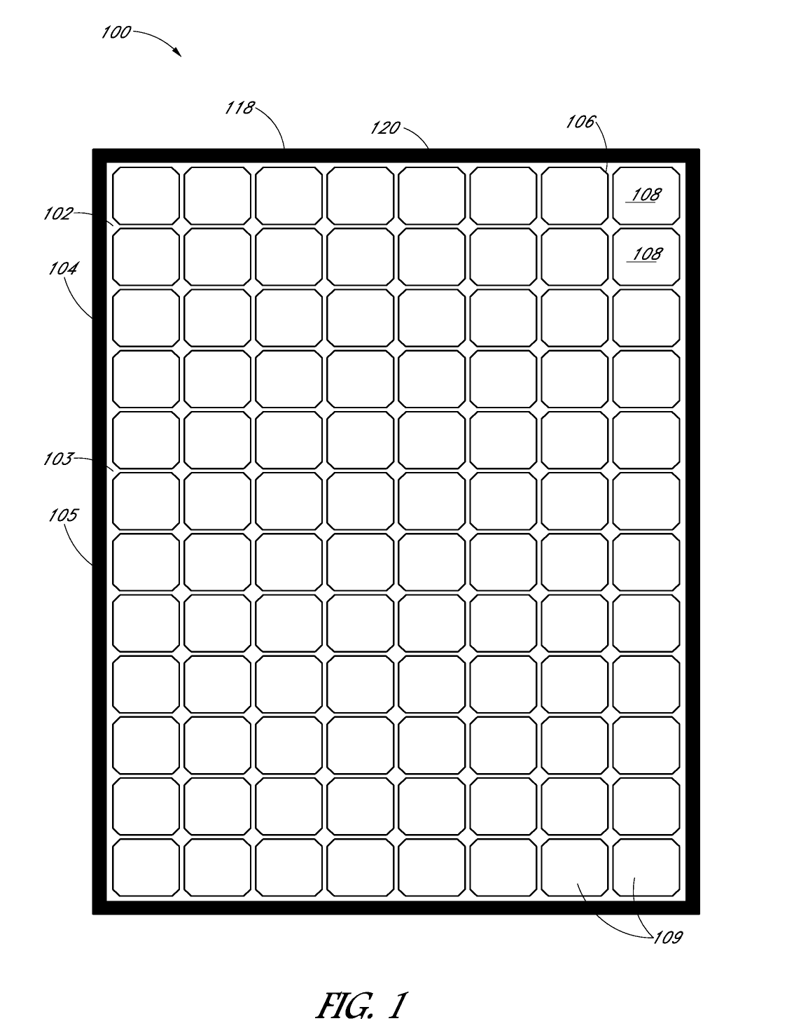

FIG. 1 illustrates a top-down view of a module 100 having a front side 102 that faces the sun to collect solar radiation during normal operation and a back side 104 opposite the front side 102. The module 100 includes a laminate 106 encapsulating a plurality of solar cells 108. In some embodiments, the module 100 can be ‘frameless.’ In frameless embodiments, the laminate 106 can define an outer edge of the PV module 100. However, in other embodiments, module 100 includes a support member or frame 120 surrounding the laminate 106, such as depicted in FIG. 1. The frame 120 can surrounding the laminate 106 to define an outer edge 118 of module 100. The frame 120 can be formed of a metal (e.g., aluminum) material, a polymeric material, or a combination thereof. In other embodiments, a support member or frame can partially surround the laminate.

The solar cells 108 can face the front side 102 and be arranged into a plurality of solar cell strings 109. The laminate 106 can include one or more encapsulating layers which surround and enclose the solar cells 108. In various embodiments, the laminate 106 includes a top cover 103 made of glass or another transparent material on the front side 102. In certain embodiments, the material chosen for construction of the cover 103 can be selected for properties which minimize reflection, thereby permitting the maximum amount of sunlight to reach the solar cells 108. The top cover 103 can provide structural rigidity to the laminate 106. The laminate 106 can further include a backsheet 105 on the back side 104. The backsheet 105 can be a weatherproof and electrically insulating layer which protects the underside of the laminate 106. The backsheet 105 can be a polymer sheet, and it can be laminated to encapsulant layer(s) of the laminate 106, or it can be integral with one of the layers of the encapsulant.

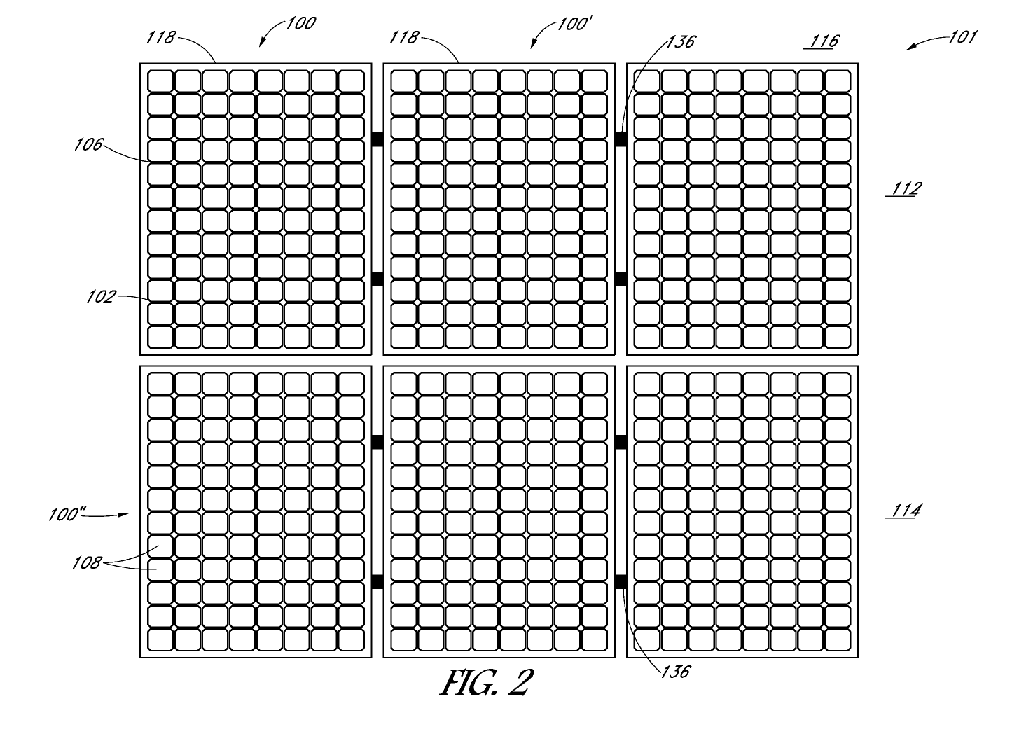

FIG. 2 illustrates a top-down view of a photovoltaic assembly 101 comprising a plurality of modules 100 (individual modules depicted as 100, 100′, 100″) arranged into a photovoltaic array 101 on a support surface or roof 116. Each module 100 has a front side 102 that faces the sun during normal operation and a laminate 106 comprising a plurality of solar cells 108. The photovoltaic array 101 can be configured in a “portrait” orientation as depicted in FIG. 2. However in other embodiments, modules can be arranged in a “landscape” orientation. Six PV modules 100 are depicted in the example of FIG. 2, however any desirable number of modules can be provided in any desirable configuration to form a PV array.

The PV assembly of FIG. 2 includes a plurality of PV modules 100 arranged into a plurality of rows of PV array 101. For ease of description, three PV modules 100 are arranged into a first row 112 and three PV modules 100 are arranged into a second row 114. In one embodiment, the first row 112 is the first or initial row installed of the array 101. The first or initial module and/or row installed of an array can act as a positioning or alignment guide for subsequent modules and/or rows installed in the array. In an embodiment, the first row 112 can be a front row of the array such that the outer edges 118 of modules 100 in first row 112 are outer front edges 118. For example, the first row 112 can be the front row of array 101 supported on roof 116, wherein row 112 is the foremost row from the perspective of the front of a building or construct comprising a support or mounting structure. In embodiments where the support structure or roof 116 is inclined or sloped, the front module(s) 100 and/or row 112 can be provided at the lowest vertical height of array 101.

In some embodiments, PV modules 100 in first row 112 can share a common mounting structure or rail and PV modules in second row 114 can share a common mounting structure or rail. In one embodiment, PV modules 100 in first row 112 do not share a common mounting structure or rail with PV modules in second row 114.

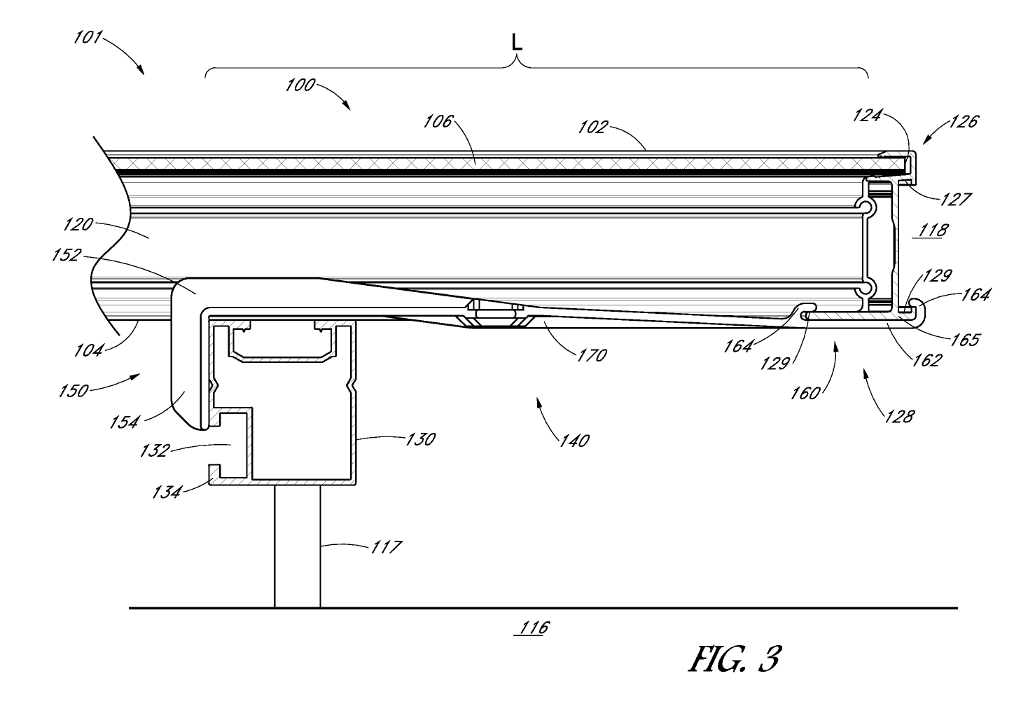

FIG. 3 depicts a side view of PV assembly 101 comprising module 100 of row 112 supported above support structure or surface 116. In an embodiment, the module 100 is disposed or supported on a mounting structure 130 (e.g. a rail) fixedly coupled to the support structure or surface 116 (e.g., a roof). The mounting structure 130 can be coupled to the support structure 116 by any desirable structure or assembly, for example by a roof anchor or L-foot generally depicted at 117. In one embodiment, the rail 130 can include an elongated piece of extruded metal. The rail 130 can include one or more grooves 132 having an aperture defined by one or more surface features, lips, or ledges 134. In some embodiments, one or more clamp assemblies 136 (visible in FIG. 2) can couple one or more PV modules to the mounting structure or rail 130. For example, one or more clamping assemblies 136 can be disposed in grooves 132 of the rail 130.

The cross sectional view of module 100 in FIG. 3 shows frame 120 surrounding the laminate 106 to define outer edge 118 of PV module 100. The frame 120 includes an upper portion 126 comprising a laminate-receiving channel 124. The upper portion 126 of frame 120 further includes an upper surface feature, flange or lip 127 at outer edge 118. Furthermore, the frame 120 includes a lower base portion 128 comprising lower surface features, flanges or lips 129 at outer edge 118 and back side 104 of module 100. In the embodiment depicted in FIG. 3, the surface features 127/129 of frame 120 include longitudinally extending ridges, however any desirable number or type of surface feature on the frame can be provided. For example, the frame can include ridges, recesses, projections, sinusoidal cross sections, saw-tooth cross sections, substantially planar surfaces, combinations thereof, or derivatives thereof. In some embodiments, the frame 120 can be integrally formed or formed as a unitary body. In other embodiments, the frame 120 can be formed from an assembly of parts.

As depicted in FIG. 3, the PV assembly 101 includes an alignment device 140 comprising a support engagement feature 150 at a first end 152 for engaging the mounting structure 130. The alignment device 140 further includes a module engagement feature 160 at a second end 162 for engaging PV module 100. In the embodiment depicted in FIG. 3, the alignment device 140 includes a body portion 170 located between the first end 152 and the second end 162.

As depicted in FIG. 3, the support engagement feature 150 of the alignment device 140 can be located at the first end 152. The support engagement feature 150 can include one or more features for engaging the mounting and/or support structure. For example, the support engagement feature 150 includes a rail engagement feature comprising a bent, angled or L-shaped head 154. In other embodiments, the support engagement feature 150 can include a fastener, a clip, a hook or any other desirable structure or feature to contact and/or engage with the mounting structure 130 and/or support structure 116.

In an embodiment, the alignment device 140 can include one or more features for engaging one or more outer surface features of module 100. As depicted in FIG. 3, the module engagement feature 160 of the alignment device 140 includes a plurality of hook features 164 for engaging lower base portion 128 of frame 120. In other words, the frame 120 includes at least one longitudinally extending ridge 129 and the engagement feature 160 of the alignment device 140 includes at least one recess 165 sized to fit the at least one longitudinally extending ridge 129 of the frame 120.

As depicted in FIG. 3, hook features 164 of alignment device 140 engage lower surface features 129 of frame 120 at back side 104 and outer edge 118 of module 100. In some embodiments, the PV module can be frameless and an alignment device can include one or more engagement features for engaging any desirable feature of the PV module (e.g., the laminate 106) at any desirable location. Alignment devices can include any desirable engagement feature including but not limited to hooks, clips, projections, recesses and a combination thereof.

In an embodiment, the alignment device 140 establishes or sets a predetermined distance between the mounting structure 130 and outer edge 118 of PV module 100. For example, the alignment device 140 can align modules and/or rows so as to form an aligned, even or level array. In one embodiment, the alignment device 140 includes a linear body portion 170 located between the support engagement feature 150 and the module engagement feature 160. The linear body portion 170 can have a predetermined length L so at to establish or set a predetermined distance between the mounting structure 130 and outer edge 118 of PV module 100 as depicted in FIG. 3. The linear body portion 170 can extend along a plane parallel to the PV module.

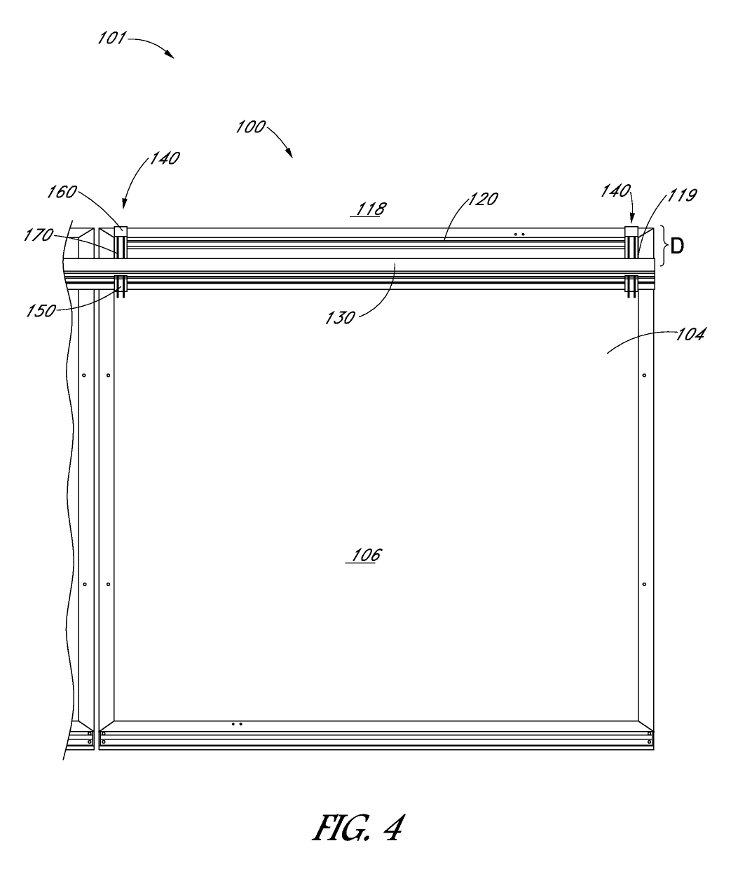

FIG. 4 depicts a bottom-up view of the back side 104 of PV assembly 101 comprising module 100. The first or front edge 118 of module 100 is aligned parallel to mounting rail 130 by two alignment devices 140. Each alignment device 140 includes a support engagement feature 150 for engaging the mounting structure 130, a module engagement feature 160 for engaging module 100 and a body portion 170 located therebetween. As depicted, the alignment devices 140 set a predetermined distance D between the support structure 130 and the module 100 in first or front row 112 of a PV array 101.

In the embodiment depicted in FIG. 4, two alignment devices 140 are provided at opposite ends of module 100. However, any desirable number of alignment devices can be provided in any desirable arrangement. For example, one alignment device can be provided, for example at a center position of module 100. As another example, more than two alignment devices can be provided. In yet other embodiments, one or more alignment devices can be provided between adjacent modules, for example between adjacent modules in a first or front row 112.

In an embodiment, a positioning or alignment device can include a polymeric material. For example, alignment devices can include materials selected from the group of: polyethylene (PE), polypropylene (PP), polystyrene (PS), polyphenylene oxide (PPO), polyvinyl chloride (PVC), polyetherether ketone (PEEK), polyamides, polycarbonates, acetal resins, acrylonitrile butadiene styrene (ABS) resins, their derivatives or combinations thereof. In some embodiments, a positioning or alignment device includes a thermoplastic material. Extrusion and/or injection molding manufacturing processes can be employed for production of a positioning or alignment device.

In one embodiment, the alignment device includes metallic elements and/or other flexible materials. For example, an alignment device can include a metal wire or stamped metal piece. For example, the alignment device can include an electrically conductive material so as to provide a grounding path between the mounting structure and the module. In another embodiment, an alignment device can include a composite material. In yet another embodiment, the alignment device can include a metallic wire embedded within a polymeric and/or thermoplastic material.

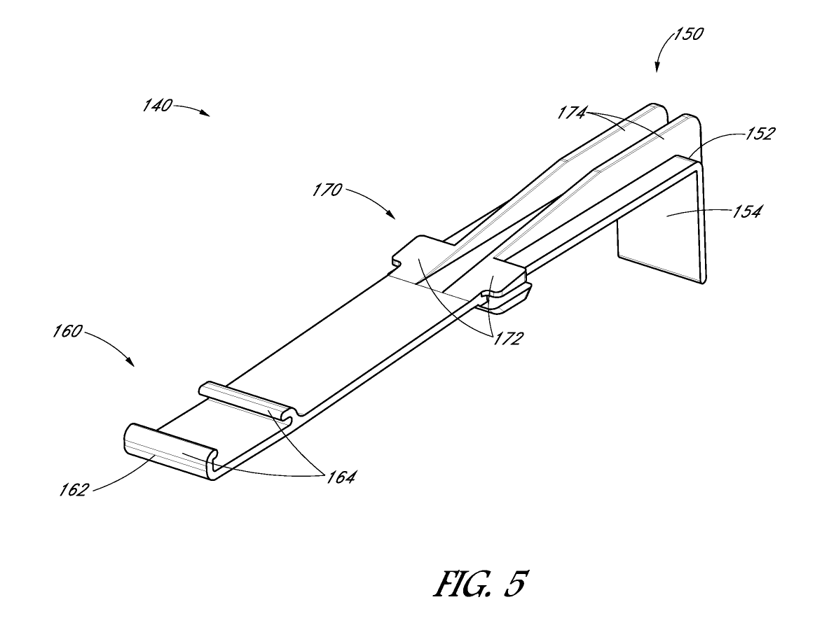

In various embodiments, a positioning or alignment device includes one or more engagement features for engaging a PV module and/or mounting structure so as to fixedly connect the alignment device to the PV module and/or mounting structure. FIG. 5 depicts alignment device 140 comprising a linear body portion 170 located between first end 152 and second end 162. The alignment device 140 includes support engagement feature 150 at first end 152. In the embodiment depicted in FIG. 5, the support engagement feature 150 includes a bent or L-shaped head 154. The alignment device 140 includes a module engagement feature 160 at the second end 162 for engaging PV module 100. The module engagement feature 160 includes a plurality of hook features 164 for engaging frame 120.

In an embodiment, the body portion of the alignment device includes engagement or stabilization features. For example, the linear body portion 170 of alignment device 140 includes engagement or stabilization features 172 for engaging an edge 119 (depicted in FIG. 4) of frame 120 at the back side 104, wherein the edge 119 is perpendicular to front edge 118 of frame 120. As another example, the linear body portion 170 of alignment device 140 can include stabilization features 174 to support the body 170 of alignment device 140. For example, stabilization features 174 can be injection molded support strips or slats for a thermoplastic alignment device 140.

In an embodiment, a positioning or alignment device establishes or sets a predetermined distance between a support or mounting structure and one or more PV modules. A positioning or alignment device can include any desirable mechanism for positioning or setting a predetermined distance, with a linear body portion extending in a plane parallel to one or more PV modules being one example. In some embodiments, a positioning or alignment device includes a feature for contacting or setting a module position relative to a mounting or support structure. For example, an alignment device includes a module engagement feature and/or mounting structure engagement feature comprising a body portion extending in a plane parallel to one or more PV modules.

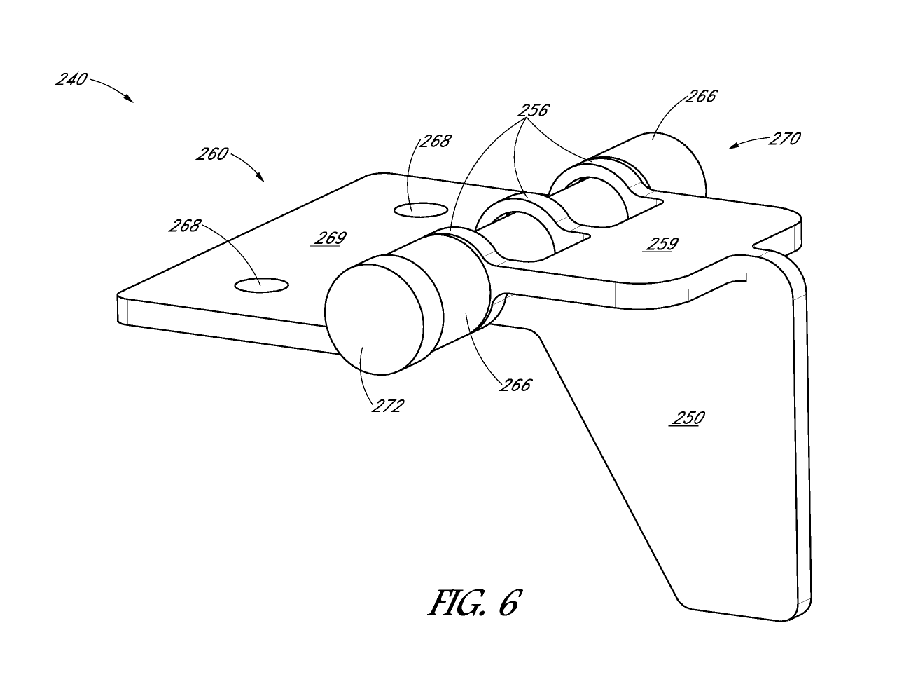

FIG. 1-5 illustrate various embodiments of PV assemblies and alignment devices. Unless otherwise specified below, the numerical indicators used to refer to components in the FIG. 6-8 are similar to those used to refer to components or features in FIG. 1-5 above, except that the index has been incremented by 100.

As another example, a positioning or alignment device can include a pivot, joint or hinge feature with a pin being sized to extend through one or more apertures of the support engagement feature and/or module engagement feature. FIG. 6 depicts an alignment device 240 comprising a hinged body portion 270 located between a support engagement feature 250 and a module engagement feature 260. The body portion 270 includes a hinge pin 272 extending through a plurality of knuckles 256 coupled to the support engagement feature 250 and a plurality of knuckles 266 coupled to the module engagement feature 260. The knuckles 256/266 each include an aperture sized and shaped to receive the hinge pin 272.

In one embodiment, the module engagement feature and/or support engagement feature includes at least one slot or hole being sized to accept a fastener. For example, the alignment device 240 of FIG. 6 includes a plurality of holes 268 extending through a hinge leaf portion 269 of the module engagement feature 260. The holes 268 of module engagement feature 260 can be sized to accept a fastener for coupling to a PV module. In the embodiment depicted in FIG. 6, the alignment device 240 includes a hinge leaf portion 259 coupled to a support engagement feature or arm 250 projecting along a plane perpendicular to the hinge leaf portions 259/269. In various embodiments, alignment devices can include a fastener, a hook, a clip, a projection or any other desirable structure or feature to contact and/or engage with the mounting structure and/or support structure.

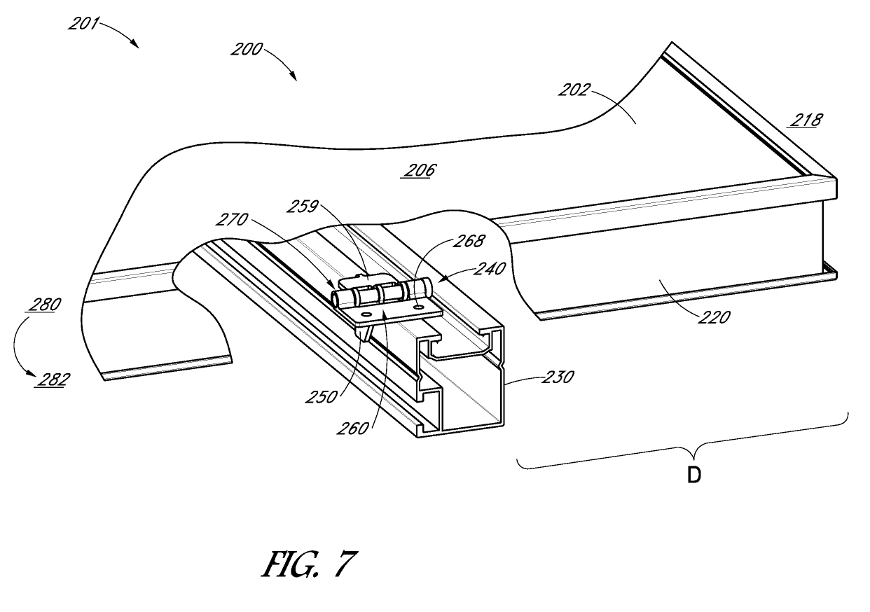

FIG. 7 depicts a perspective view of PV assembly 201 comprising alignment device 240 setting a position of PV module 200 on mounting structure 230. The module engagement feature 260 of alignment device 240 is coupled to frame 220 of module 200 by fasteners (e.g., screws, bolts, pins, rivets, etc.) extending through holes 268. The support engagement feature 250 of alignment device 240 engages or contacts rail 230 so as to set the distance D between the support structure 230 and front edge 218 of module 200.

In various embodiments, the alignment device includes a pivot, joint or hinge for swinging between a plurality of positions. For example as depicted in FIG. 6 and FIG. 7, the alignment device 240 includes a hinge body 270 for alternating or swinging between a first position 280 and a second position 282 (second position 282 depicted in FIG. 7). For example, the first position 280 can maintain a closed or secured state. The second position 282 can maintain an open state and set the predetermined distance D between the support structure 230 and edge 218 of PV module 200 by bumping or catching the projection of the support engagement feature 250 on rail 230.

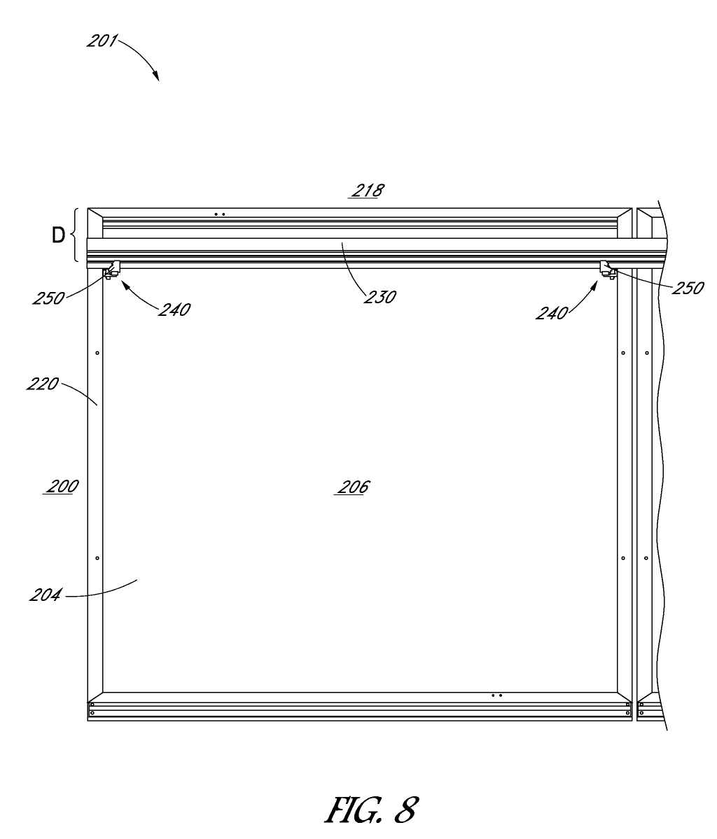

FIG. 8 depicts a bottom-up view of the back side 204 of PV assembly 201 comprising alignment device 240 in second position 282 so as to set a position of PV module 200 on mounting structure 230. In particular, the support engagement feature 250 of the alignment device 240 contacts rail 230 so as to set the predetermined distance D between the rail 230 and edge 218 of PV module 200. In the embodiment depicted in FIG. 8, two alignment devices 240 are provided at opposite ends of module 100. However, any desirable number of alignment devices can be provided in any desirable arrangement.

As depicted in FIG. 8 alignment devices 240 are located on the back side 202 of PV module 200. As another example depicted in FIG. 4, 8 alignment devices 140 are located on the back side 102 and front edge 118 of PV module 200. However, alignment devices can be provided in any desirable arrangement or position including on one or more sides of a module, at the back of a module, at the front of a module, or any combination thereof.

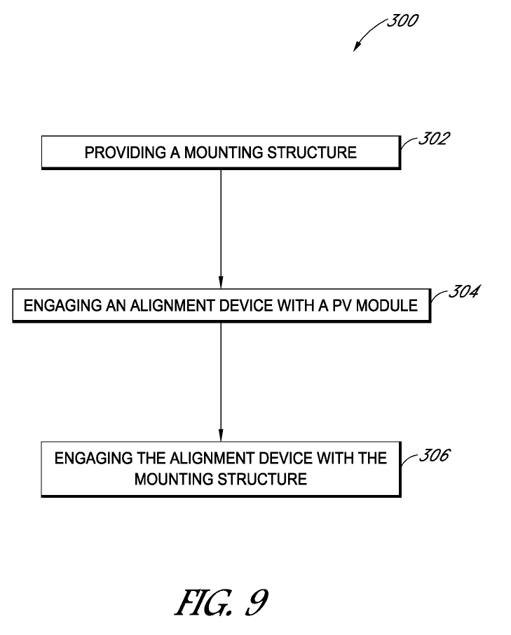

Improved methods for installing or assembling a plurality of PV modules to form PV arrays are also described herein. FIG. 9 depicts a flowchart 300 listing operations in a method for assembling a PV array comprising a plurality of PV modules arranged into a plurality of rows. Referring to operation 302 of flowchart 300, a method for installing a plurality of PV modules to form a PV array includes providing a mounting structure for PV modules which can include fixedly coupling a rail to a support surface (e.g., a roof). The method further includes engaging an alignment device with a PV module at operation 304, for example a PV module in a front row of the PV array. Referring to operation 306 of flowchart 300, a method for installing a plurality of PV modules to form a PV array further includes engaging an alignment device with the mounting structure so as to set a predetermined distance between the mounting structure and the module, thereby aligning PV modules in the front row of the PV array.

The above specification and examples provide a complete description of the structure and use of illustrative embodiments. Although certain embodiments have been described above with a certain degree of particularity, or with reference to one or more individual embodiments, those skilled in the art could make numerous alterations to the disclosed embodiments without departing from the scope of this invention. As such, the various illustrative embodiments of the methods and systems are not intended to be limited to the particular forms disclosed. Rather, they include all modifications and alternatives falling within the scope of the claims, and embodiments other than the one shown can include some or all of the features of the depicted embodiment. For example, elements can be omitted or combined as a unitary structure, and/or connections can be substituted. Further, where appropriate, aspects of any of the examples described above can be combined with aspects of any of the other examples described to form further examples having comparable or different properties and/or functions, and addressing the same or different problems. Similarly, it will be understood that the benefits and advantages described above can relate to one embodiment or can relate to several embodiments. For example, embodiments of the present methods and systems can be practiced and/or implemented using different structural configurations, materials, and/or control manufacturing steps. The claims are not intended to include, and should not be interpreted to include, means-plus- or step-plus-function limitations, unless such a limitation is explicitly recited in a given claim using the phrase(s) “means for” or “step for,” respectively.

What is claimed is:

1. A photovoltaic (PV) assembly comprising:
a rail fixedly coupled to a support surface;
a plurality of PV modules disposed on the rail, the plurality of PV modules being arranged into a first row of a PV array, each PV module having a front side that faces the sun to collect solar radiation during normal operation and a back side opposite the front side, each PV module comprising:
a laminate encapsulating a plurality of solar cells, and
a frame surrounding the laminate to define an outer front edge of the PV module;
a plurality of alignment devices located on the back side of the plurality of PV modules in the first row of the PV array, each alignment device comprising:
a first and a second end,
a linear body portion located between the first and second ends, the linear body portion having a predetermined length,
a rail engagement feature located at the first end for engaging the rail, and
a PV module engagement feature located at the second end for engaging the outer front edge of one of the plurality of PV modules in the first row of the PV array; and,
a plurality of clamp assemblies coupling the plurality of PV modules to the rail;
wherein the plurality of alignment devices set a predetermined distance between the rail and the outer front edges of the plurality of PV modules so as to align PV modules in the first row of the PV array.

2. The PV assembly according to claim 1, wherein the rail engagement feature comprises an L-shaped head.

3. The PV assembly according to claim 1, wherein the PV module engagement feature comprises a hook feature.

4. A photovoltaic (PV) assembly comprising:
a mounting structure;
at least one PV module having an outer edge, the at least one PV module being supported on the mounting structure; and
an alignment device comprising:
a support engagement feature for engaging the mounting structure, and
a module engagement feature for engaging the at least one PV module;
wherein the alignment device sets a predetermined distance between the mounting structure and the outer edge of the at least one PV module.

5. The PV assembly according to claim 4, wherein the at least one PV module is located in a front row of a PV array and wherein the alignment device sets the predetermined distance between the mounting structure and an outer front edge of the at least one PV module.

6. The PV assembly according to claim 4, wherein the alignment device further comprises a linear body portion located between the support engagement feature and the module engagement feature, the linear body portion having a predetermined length.

7. The PV assembly according to claim 4, wherein the alignment device comprises a hinge feature located between the support engagement feature and the module engagement feature.

8. The PV assembly according to claim 7, wherein the hinge feature comprises a hinge pin being sized to extend through at least one aperture of the support engagement feature and at least one aperture of the module engagement feature.

9. The PV assembly according to claim 4, wherein the PV assembly further comprises a plurality of clamp assemblies coupling the at least one PV module to the mounting structure.

10. The PV assembly according to claim 4, wherein the support engagement feature comprises an L-shaped head.

11. The PV assembly according to claim 4, wherein the module engagement feature comprises a hook feature.

12. The PV assembly according to claim 4, wherein the module engagement feature comprises at least one slot being sized to accept a fastener.

13. The PV assembly according to claim 4, wherein the at least one PV module further comprises a frame surrounding a laminate.

14. The PV assembly according to claim 13, wherein the frame comprises at least one longitudinally extending ridge.

15. The PV assembly according to claim 14, wherein the support engagement feature of the alignment device comprises at least one recess sized to fit the least one longitudinally extending ridge of the frame.

16. The PV assembly according to claim 4, wherein the alignment device is located on a back side of the at least one PV module.

17. The PV assembly according to claim 4, wherein the PV module engagement feature engages a front side edge of the at least one PV module.

18. The PV assembly according to claim 4, wherein the PV module engagement feature engages a bottom edge of the at least one PV module.

19. The PV assembly according to claim 4, wherein the alignment device comprises a thermoplastic material, a metallic material or a combination thereof.

20. An alignment device for aligning a plurality of PV modules in a front row of a PV array and supported on a support structure, the alignment device comprising:
a first end, and a second end;
a linear body portion located between the first end and the second end, the linear body portion having a predetermined length;
a support engagement feature located at the first end for engaging a support structure; and
a module engagement feature located at the second end for engaging one of the plurality of PV modules;
wherein the alignment device sets a predetermined distance between the support structure and the plurality of PV modules in a front row of a PV array.
